(19) United States
(12) Patent Application Publication
(10) Pub. No.: US 2004/0222518 A1
(43) Pub. Date: Nov. 11, 2004

(54) Ball grid array with bumps

(75) Inventors: Belgacem Haba, Cupertino, CA (US); Yoichi Kubota, Pleasanton, CA (US)

Correspondence Address: LERNER DAVID, LITENBERG, KRUMHOLZ & MENTLIK, 600 SOUTH AVENUE WEST, WESTFIELD, NJ, 07090, US

(73) Assignee: Tessera, Inc., San Jose, CA (US)

(21) Appl. No.: 10/786,819

(22) Filed: Feb. 25, 2004

Related U.S. Application Data
(60) Provisional application No. 60/449,684, filed on Feb. 25, 2003.
(60) Provisional application No. 60/456,618, filed on Mar. 21, 2003.

(51) Int. Cl. H01L 23/48

(52) U.S. Cl. 257/734

(57) ABSTRACT

A semiconductor chip assembly includes a chip carrier having a dielectric layer and electrically-conductive terminals in the form of projecting bumps formed integrally with traces on the dielectric layer. The bumps have convex surfaces and desirably are hollow and deformable. The convex bottom ends of the bumps may be bonded to the contact pads on the surfaces of a circuit panel by a small amount of solder or other bonding material. The structure provides a sound joint between the contact pads and the bumps and avoids the need for relatively large solder balls. The assembly can be made using techniques well-integrated with conventional surface-mounting techniques.

### CROSS-REFERENCE TO RELATED APPLICATIONS

The present application claims benefit of U.S. Provisional Patent Application Ser. No. 60/456,618, filed Mar. 21, 2003, and 60/449,684, filed Feb. 25, 2003, the disclosures of which are incorporated by reference herein.

### BACKGROUND OF THE INVENTION

The present invention relates to microelectronic packaging and sockets.

Semiconductor chips are formed as a small, generally flat bodies with large and front rear surfaces and with contacts on the front surface electrically connected to electrical devices within the body. Although a semiconductor chip can be mounted directly to a circuit board, this requires special handling and mounting techniques. Therefore, chips are ordinarily provided as “packaged” units. A packaged chip includes the chip itself together with structures which at least partially cover surfaces or edges of the chip and which typically define terminals distinct from the contacts of the chip itself but electrically connected to such contacts. The packaged chip can be handled as a unit and can be mounted to external structures such as circuit boards using conventional techniques.

One form of packaged chips which has become increasingly popular is the “ball grid array” package. Such a package incorporates a chip carrier having a dielectric layer and terminals on the dielectric layer. The chip overlies a surface of the dielectric layer, with the front or back surface of the chip facing toward the dielectric layer. The terminals on the dielectric layer are connected by internal leads or wires of the package to the contacts on the chip. Typically, the terminals are formed as flat, disc-like elements integral with traces on the dielectric layer.

Such a package ordinarily is mounted on a circuit panel having contact pads exposed at a top surface by placing the package over the panel so that the terminals of the package are aligned with the contact pads on the package, with solder balls disposed between each terminal and the aligned contact pad. The solder balls are remelted or “reflowed” so as to form physical and electrical interconnections between the terminals and the contact pads. This type of mounting is compatible with the normal surface-mounting techniques used for mounting many components to circuit bumps. Ordinarily, the solder balls are prepositioned on the terminals of the packaged chip as part of the package manufacturing process, so that the entire unit can simply be placed on the circuit board with a flux if necessary and reflowed to complete the mounting process.

Although ball grid array packaging has been widely adopted, still further improvements would desirable. Typically, ball grid array packages are tested by engaging them with a test fixture having test contacts in a pattern corresponding to the pattern of contact pads on the circuit panel and applying signals and power to the chip through the solder balls and terminals. It is difficult to test ball grid array packages prior to mounting the solder balls on the contact pads. The solder balls project from the package and hence can be more readily engaged with a test fixture such as a socket. However, the solder tends to contaminate the test fixture as the test fixture is used repeatedly. Further, the solder typically used in a standard ball grid array package has a high lead content. There is increasing concern about this lead contaminating landfills and water supplies when the parts are disposed of. For these and other reasons, further enhancements would be desirable.

### SUMMARY OF THE INVENTION

One aspect of the invention provides a chip carrier. A chip carrier according to this aspect of the invention desirably includes a dielectric layer having an inner surface facing upwardly and an outer surface facing downwardly, as well as conductive traces on the dielectric layer. The chip carrier according to this aspect of the invention desirably includes conductive bumps formed integrally with the traces. The conductive bumps project downwardly from the traces and have bottom ends which are adapted for bonding to contact pads on a circuit panel. As further discussed below, the integrally formed bumps and traces most preferably are formed from a single piece of metal, and the dielectric layer desirably is a coherent, self-supporting structure which can support and position the bumps and traces independently of any chip to which the carrier may subsequently be attached.

Most preferably, some or all of the bumps on the chip carrier are generally cup-shaped structures, preferably hollow, with a closed end of the cup shape defining the bottom end of the bump and an open end of the cup shape facing upwardly. Thus, the bumps desirably have a bottom wall portion defining the bottom end of the cup shape and first and second wall portions joining the bottom wall portion and extending upwardly therefrom, at least one of such wall portions joining one of the traces. Desirably, some or all of the bumps have exterior surfaces in the form of a surface of revolution about a generally vertical axis. The bumps desirably define lead-in surfaces sloping upwardly and outwardly around the entire periphery of the bump, adjacent the bottom end of the bump. In one arrangement, the traces are disposed on the inner side of the dielectric layer, and the bumps extend at least partially through the dielectric layer. The bumps may extend entirely through the dielectric layer, so that the bottom ends of the bumps are disposed below the outer surface of the dielectric layer.

A further aspect of the invention provides a packaged chip which includes a chip having front and rear surfaces and contacts on the front surface, as well as a chip carrier which may include the features discussed above. The dielectric layer desirably extends beneath the chip, and the inner surface of the dielectric layer of the chip carrier faces upwardly toward the chip. Desirably, at least some of the bumps are disposed beneath the chip. The chip carrier may have leads formed integrally with the traces and bumps, such leads being bonded to contacts of the chip. Alternatively, the chip carrier may include bonding pads electrically connected to the traces and desirably formed integrally therewith, as well as bond wires formed separately from the traces and bonding pads, the bond wires connecting the bonding pads to the contacts. The packaged chip may include the chip in a face-down orientation, such that the front or contact-bearing surface of the chip faces toward the chip carrier, or in a face-up orientation, with the rear surface of the chip facing downwardly toward the chip carrier. The bottom ends of the bumps desirably are movable with respect to the chip. As further explained below, movability of the bump bottom ends may include some movability attributable to deformability of the bumps themselves. The packaged chip may further include a spacer layer disposed between the chip and the dielectric layer of the chip carrier. This spacer layer optionally may be a compliant structure which contributes to movability of the bump bottom ends.

Yet another aspect of the invention provides a microelectronic assembly which may include a packaged semiconductor chip, as discussed above, in conjunction with a circuit panel having a top surface and contact pads exposed at the top surface. The bottom ends of the bumps on the chip carrier desirably are bonded to the contact pads on the circuit panel. As further discussed below, only a small amount of conductive bonding material need be used to join the bottom ends of the bumps to the contact pads of the circuit panel. For example, the conductive bonding material may include a thin film extending over a portion or all of the desirably convex bottom surfaces of the bumps and may form fillets extending from the contact pads to locations on the vertically-extensive wall surfaces of the bumps, above the bottom ends of the bumps. These fillets may extend entirely around each individual bump. Such a structure forms a strong joint with good resistance to stresses which may be imposed upon on it in service or in manufacture as, for example, stresses resulting from differential thermal expansion of the circuit panel and elements of the chip package such as the chip itself. In certain preferred embodiments, the bumps may provide flexibility similar to that imparted by solder balls having a height equivalent to that of the bumps. However, the assembly contains substantially less solder than an assembly including such large solder balls.

Yet another aspect of the invention provides methods of making microelectronic assemblies. The assembly methods according to this aspect of the invention may include a step of temporarily engaging a chip assembly such as those discussed above with a test fixture, so that the bottom ends of the bumps engage test contacts on the fixture, and testing the chip assembly by transmitting signals between at least some of the engaged bumps and test contacts. After testing, the assembly desirably is disengaged from the test fixture and mounted on a circuit panel by bonding the bottom ends of the bumps to contact pads on the circuit panel. During the temporary engagement step, the bottom ends of at least some of the bumps desirably are displaced vertically relative to the bottom ends of others of the bumps. Here again, the displacement of the bump bottom ends may arise at least in part from deformation of the bumps themselves.

A still further aspect of the present invention provides methods of making chip carriers such as those discussed above. The methods of making the chip carriers desirably includes the step of uniting a metal with a dielectric layer having inner and outer surfaces, forming traces on the dielectric layer from the metal, and forming metallic bumps by deforming the metal. The uniting, bump-forming and trace-forming steps preferably are performed so that the bumps are integral with the traces and project downwardly from the traces. The bump-forming step may be performed after the step of uniting the metal with the dielectric layer as, for example, by deforming the metal through openings in the dielectric layer. The deforming step may be performed before or after the trace-forming step. Fabrication of the chip carrier may include other steps as, for example, forming leads integral with the traces and performing operations on the dielectric layer itself, such as forming bond windows. As discussed below, certain preferred methods according to this aspect of the invention can form chip carriers with bumps as discussed above at little or no additional cost over and above that incurred in forming otherwise comparable chip carriers having flat terminals.

As also described below, the bumps and chip carriers discussed herein can be used in other assemblies as, for example, to provide a socket in which the open ends of cup-shaped bumps serve as contacts for receiving other structures. In a socket according to yet another aspect of the invention, the bumps provide a “stand-off” supporting a dielectric element above a substrate and allow flexure of the dielectric element, so that another conductive element can be engaged with sockets mounted to the dielectric element, remote from the bumps themselves. Also, packaged chips as discussed above can be stacked. In one such arrangement, the bumps incorporated in one packaged chip serve as sockets receiving the bumps of the next adjacent chip carrier.

These and other objects, features and advantages of the present invention will be more readily apparent from the detailed description of the preferred embodiments set forth below, taken in conjunction with the accompanying drawings.

### BRIEF DESCRIPTION OF THE DRAWINGS

FIG. 1 is a diagrammatic top plan view depicting certain elements of a chip carrier during a process of forming the chip carrier.

FIG. 2 is a sectional view taking along line 2-2 in FIG. 1.

FIG. 3 is a view similar to FIG. 2, but depicting the elements at a later stage during the process.

FIG. 4 is a diagrammatic sectional view depicting a packaged chip incorporating the chip carrier of FIGS. 1-3.

FIG. 5 is a diagrammatic view depicting the packaged chip of FIG. 4 during one stage of a testing and assembling process.

FIG. 6 is a diagrammatic sectional view depicting a microelectronic assembly incorporating the packaged chip of FIGS. 4 and 5 in conjunction with a circuit panel.

FIG. 7 is a fragmentary view on an enlarged scale depicting a portion of the assembly shown in FIG. 6.

FIG. 8 is a diagrammatic sectional view similar to FIG. 6, but depicting an assembly in accordance with a further embodiment of the invention.

FIG. 9 is a diagrammatic sectional view depicting a packaged chip in accordance with a further embodiment of the invention.

FIG. 10 is a fragmentary, diagrammatic perspective view depicting certain portions of a chip carrier and assembly in accordance with a further embodiment of the invention.

FIG. 11 is a fragmentary, diagrammatic perspective view depicting portions an assembly in accordance with yet another embodiment of the invention.

FIG. 12 is a diagrammatic elevational view depicting an assembly in accordance with yet another embodiment of the invention.

FIG. 13 is a fragmentary, diagrammatic sectional view depicting portions of the assembly shown in FIG. 12.

FIG. 14 is diagrammatic sectional view depicting portions of a socket in accordance with a further embodiment of the invention.

FIGS. 15-18 are diagrammatic sectional views depicting portions of a chip carrier in accordance with a further embodiment of the invention during progressively later stages in manufacture of the chip carrier.

FIG. 19 is a diagrammatic sectional view depicting a portion of a chip carrier in accordance with one embodiment of the invention during a stage in a manufacturing process.

FIG. 20 is a diagrammatic sectional view depicting a portion of a chip carrier in accordance with yet another embodiment of the invention.

FIG. 21 is a fragmentary, diagrammatic sectional view depicting portions of yet another chip carrier in accordance with a further embodiment of the invention.

FIG. 22 is a fragmentary, diagrammatic sectional view depicting a portion of an assembly in accordance with a still further embodiment of the invention.

### DESCRIPTION OF THE PREFERRED EMBODIMENTS

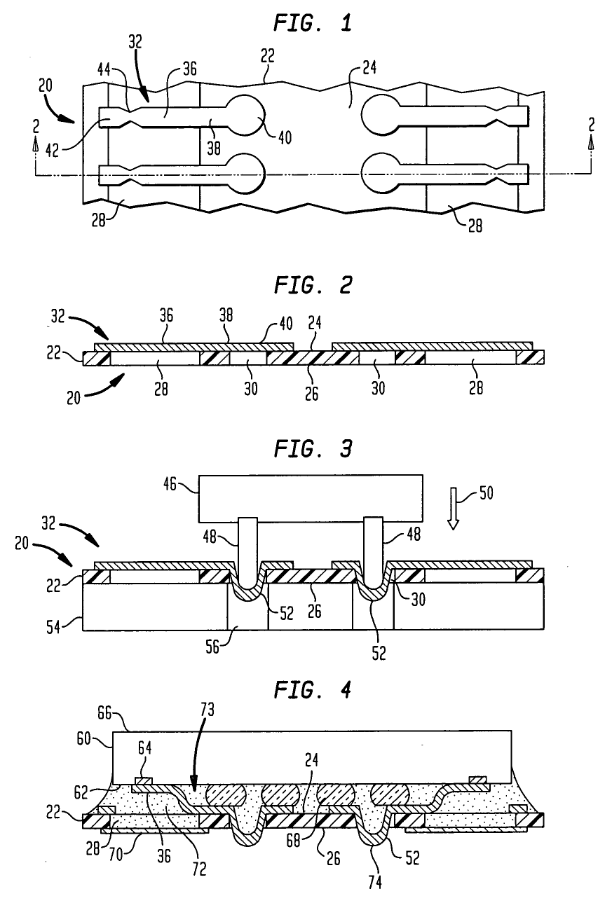

A method of making a package according to one embodiment of the invention utilizes a substrate 20 incorporating a dielectric layer 22. Only a small portion of the dielectric layer is shown in plan view in FIG. 1. Layer 22 is generally planar plate-like or sheet-like structure having an inner side 24 seen in FIG. 1 and an oppositely facing outer side 26 (FIG. 2). For example, layer 22 may be a circuit board formed from a conventional material such as FR4, FR5 or BT resin reinforced composite or a flexible circuit panel formed from a relatively thin layer of reinforced or unreinforced polymeric material such as, for example, polyimide. Layer 22 has bond windows 28 extending through the layer from the inner side to the outer side and also has bump openings 30 (FIG. 2) extending through it. Substrate 20 further includes a metallic layer 32 disposed on the inner surface 24 of dielectric layer 22. Metallic layer 32 incorporates a large number of lead units. Each such unit includes a lead 36 projecting across one of the bond windows 28; a trace 38 integral with the lead and extending across a portion of the inner surface and a bump-forming element 40 integral with the trace 38 and lead 36 disposed over one of the bump openings 30. The ends of leads 36 remote from the associated traces 38 are anchored to the dielectric layer by anchors 42 on the opposite side of the bond windows from the traces 38. Each anchor is connected to the associated lead by the relatively weak, frangible element 44 having tensile strength substantially smaller than tensile strength of lead 36. For example, each frangible element may be a section of smaller cross sectional area than the lead. In the particular arrangement illustrated, the bond windows are elongated, slot-like structures and numerous leads 36 project across each bond window. However, any arrangement of leads and bond windows can be employed. The structure of the leads and bond windows may be, for example, as shown in U.S. Pat. Nos. 5,915,752 and 5,489,749.

The substrate in the condition illustrated in FIGS. 1 and 2 may be fabricated by conventional processes as, for example, by uniting a continuous layer of metal with a dielectric layer and selectively etching the metallic layer to form the lead units, or by uniting metal and dielectric by depositing a metallic layer selectively onto the surface of the dielectric layer to form the lead units. The bond windows 28 and bump openings 30 may be formed by ablating, etching or mechanically punching the dielectric layer either before or after uniting the dielectric layer with the metallic layer. As mentioned above, only a small fragment of substrate is depicted in FIGS. 1 and 2. The substrate may be provided as a large, continuous tape or sheet suitable for forming numerous chip carriers to be associated with numerous chips, or can be provided as smaller units down to a substrate suitable for forming a chip carrier for a single chip.

In the next stage of the process, metallic layer 32 and particularly the bump-forming elements 40 are deformed by engaging the metallic layer with a punch 46 having projections 48 and moving the punch downwardly, in the direction indicated by arrow 50 in FIG. 3. The tips of the projections engage the bump-forming elements 40 of the metallic layer and deform those bump-forming elements into bumps 52 which are generally cup-shaped, hollow shells surrounding the tips of the projections. The bumps 52 extend downwardly through bump openings 30 so that the bumps 52 project beyond the lower or outer surface 26 of the dielectric layer.

Bumps 52 are formed integrally with traces 38. That is, a single metal forms at least a part of the trace and at least a part of the downwardly-extending bump, and this single metal extends into the bump and into the trace as a continuous body without a weld or joint. Either or both of the bump and the trace can include additional metals, which may be the same or different, and which may or may not be continuous with one another. The bumps can be formed from essentially any metal which has the desired conductive and bondability properties. Most commonly, the bumps and traces are formed from copper or a copper alloy, with or without a layer of gold or other oxidation-resistant, bondable metal. Such additional metals can be applied by conventional plating processes. The bumps can be disposed side by side or in arrays with small spacings between adjacent bumps, as, for example, center-to-center distances less than about 1 mm. The bumps typically protrude from the outer surface of the dielectric by about 10 to about 150 microns.

In this condition, that portion of the substrate 20 forming each chip carrier, together with the traces 38, leads 36 and bumps 52 on such portion of the substrate, form a coherent, self-supporting structure. That is, the substrate supports the traces and bumps, and holds these elements at least substantially in position relative to one another while the chip carrier is in existence as an element separate from a chip to which the carrier may be attached in a later stage of manufacture. Stated another way, a coherent, self-supporting chip carrier is an element which can retain its structure and configuration prior to attachment to a chip or other structure. A coherent, self-supporting chip carrier is distinguished, for example, from a structure which is built up upon the surface of a chip, for example by applying a succession of coatings on the chip surface.

In a further process step, the chip carrier is then assembled with a chip 60 (FIG. 4) having a front face 62 with electrical contacts 64 thereon and having an oppositely facing rear face 66. In the particular embodiment illustrated in FIG. 4, the chip is disposed over the inner surface 24 of the dielectric layer and the front face 62 of the chip faces downwardly toward the inner face of the dielectric layer. As further explained below, other arrangements can be employed. The leads 36 are bonded to the contacts 64 on the chip as, for example, by forcing the leads into engagement with the contacts using a sonic bonding tool in a process which also breaks the frangible elements 44 (FIG. 1) and disconnects the leads from the anchors. During the lead-bonding process, the chip 60 is spaced slightly from the dielectric layer and metallic layer of the chip carrier. For example, the plurality of small dielectric supports or “nubbins” 68 may be interposed between the front face of the chip and the chip carrier. Alternatively, one or a few preformed pads of a die attach material as discussed below in connection with FIG. 9 may be positioned on the chip or on the chip carrier, or fabricated as part of the chip carrier, so that the pad or pads covers a substantial portion or all of the chip surface and supports the chip above the chip carrier. In a further arrangement, a unitary pad or pads of die attach material can be made from a flowable die attach material applied to the surface of the chip or to the chip carrier prior to engaging the chip with the chip carrier.

After lead bonding, bond windows 28 are closed by a cover layer 70 which may be a very thin dielectric layer of the type commonly employed as a solder mask. Cover layer 70 may be provided over the entire outer surface 26 of the dielectric layer or, alternatively, may be provided only over the bond windows. Following application of the cover layer, an encapsulant 72 is introduced into the space between the chip and the dielectric layer and around the nubbins so as to form a composite spacer layer 73 including the encapsulant 72 and the nubbins 68. The encapsulant and the nubbins optionally may be formed from relatively soft materials as, for example, gels, elastomers, epoxies or other polymers, or from relatively rigid materials, or from a combination of relatively soft and relatively rigid materials. In the embodiment where the nubbins 68 are replaced by a larger pad or pads of die attach material, the pad or pads forms a part or all of the spacer layer 73. The cover layer 70 serves to prevent leakage of the encapsulant through the bond windows 28 during this process. The bumps 52 effectively seal the bump openings 30. Encapsulation processes of this general nature are described in U.S. Pat. Nos. 5,766,987; 5,659,952; 6,130,116 and 6,329,224, the disclosures of which are hereby incorporated by reference herein. In the embodiment illustrated, the cover layer 70 is left in place as a part of the finished product. In this embodiment, the cover layer effectively merges with dielectric layer 22 and forms a part of the dielectric layer in the finished article. In a variant of this process, the cover layer is removed after the encapsulant is injected and cured.

The resulting packaged semiconductor chip has self-supporting, generally cup-shaped bumps 52 electrically connected to the contacts 64 of the chip. Bumps 52 project downwardly (in the direction towards the bottom of drawing as seen in FIG. 4) and outwardly beyond the outer surface 26 of the dielectric layer (and beyond the cover layer 70). The encapsulant 72 which forms a portion of the supporting layer may also fill the interiors of cup-shaped bumps 52. Each bump 52 defines a rounded, convex bottom end 74 remote from the dielectric layer and chip at its bottom extremity. As seen in greater detail in FIG. 7, the exterior surface of the bottom end of the bump slopes upwardly in the direction outwardly away from the center of the bottom surface. Stated another way, a line 75 tangent to the exterior surface of the bump at a point slopes upwardly in the direction outwardly away from a vertical axis 77 extending through the bottom-most extremity of the bump. Desirably, this property is true for at least those points on the surface of the bump near the periphery of the bump, i.e., remote from axis 77, and positioned below the bottom surface 26 of the dielectric layer. The bump thus defines a sloping lead-in surface around the periphery of the bump and adjacent the bottom end of the bump. The exterior surface of the bump may be in the form of a surface of revolution about axis 77, and the bottom extremity of the bump may be in the form of a sphere or a sector of a sphere. In this embodiment, the exterior surface of bump 52 is a continuous surface entirely encircling axis 77 from the bottom extremity of the bump to the outer surface 26 of the dielectric layer, with no holes or openings to the interior of the bump below the outer surface of the dielectric layer. Further, the bump is connected to the dielectric layer around the entire circumference of the bump, on all sides of axis 77.

If the foregoing steps are performed using a chip carrier or substrate large enough to accommodate numerous chips, the individual packages can be separated by severing the dielectric layer at this stage of the process or after the testing phase discussed below.

In the next phase of the process, the packaged chips are tested by engaging them with a test fixture 80 having electrically conductive elements 82 exposed at the top surface of the fixture. The conductive elements may incorporate openings 84 of the type commonly employed in sockets for receiving solder balls. Examples of such sockets are disclosed in U.S. Pat. Nos. 5,802,699; 5,980,270; and 6,086,386, the disclosures of which are incorporated by reference herein. By way of example, the socket conductive elements 82 may include elements such as prongs or ridges (not shown) extending into or over openings 84 for providing high contact pressure at localized areas. Because the bumps 52 project downwardly below the dielectric layer, the bumps can be engaged in such openings in substantially the same way as solder balls. During the testing process, the packaged chip can be forced downwardly into engagement with the socket as, for example, by engaging the top surface of the packaged chip with a platen 86 and squeezing the packaged chip between the platen and the test fixture 82. During the testing procedure, the packaged chip is electrically tested by transmitting power, signals or both to the chip through bumps 52 and through the associated leads. The sloping lead-in surfaces on the bumps facilitate engagement of the bumps with the openings 84 of the test fixture, and also wipe the edges of the openings and related features during engagement.

In the testing process, the bottom ends 74 of the individual bumps 52 desirably can be displaced independently of one another in the vertical direction upwardly and downwardly, toward and away from the chip 60. Although the present invention is not limited by any theory of operation, it is believed that the vertical displaceability of the bottom ends can be provided by deformation of the individual bumps 52 such as flattening of the convex bottom ends 74; by more generalized deformation of the bumps; by localized deformation of the dielectric layer 22; by localized deformation of spacer layer 73 to provide vertical movement of the entire bump or to allow tilting of individual bumps as, for example in the directions indicated by arrow 102; or by some combination of these factors. The relative importance of each of these factors will vary with the particular structure. However, regardless of the mechanism by which vertical displaceability is provided, vertical displaceability of the bump bottom ends facilitates reliable engagement of the bumps with the conductive elements 82 of socket or test fixture 80, even where the bump bottom ends 74, socket conductive elements 82 or both are slightly out-of-plane. Because the bump bottom ends can be displaced, reliable engagement can be achieved even where conductive elements 82 of the socket or test fixture 80 are fixed, relatively rigid structures. A test fixture with fixed, rigid conductive elements can be simple and relatively inexpensive. However, a test fixture with resilient conductive elements can be used if desired.

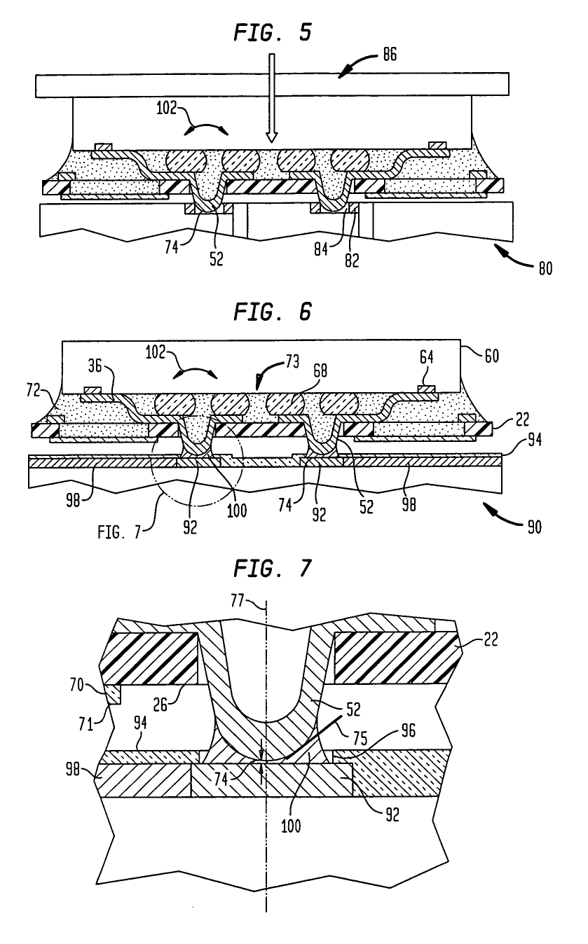

Moreover, the bumps can be engaged with contacts on the test fixture which are substantially planar and which do not incorporate the openings 84 in the contacts discussed above with reference to FIG. 5. For example, the contacts may be flat structures similar to the contact pads 92 of the circuit panel discussed below. Here again, although the present invention is not limited by any theory of operation, it is believed that vertical displaceability of the bump bottom ends, the ability of the bumps 52 to tilt, and localized deformation of the bump bottom ends contribute to the ability of the bumps to make reliable contact with a planar contact pad. Thus, it is believed that some or all of these factors may provide “wipe” or relative movement between the surface of the bump and the surface of the contact pad.

After testing, the packaged chip can be mounted on a circuit panel 90 having pads 92 exposed at a top surface of the panel. As best seen in FIGS. 6 and 7, the circuit panel has a solder mask layer 94 overlying the top surface and apertures 96 in the solder mask layer, the pads being exposed through the apertures in this solder mask layer. The circuit panel also has traces 98 connected to the pads. The traces may extend within the circuit panel or on either side thereof and may be provided in any pattern.

The bottom ends 74 of the bumps 52 are bonded to contact pads 92 by a thin layer of a solder or other fusible electrically conductive bonding material. The bonding material or solder wets the metal of the bump 52 as well as the metal of the contact pad. Thus, the solder or other bonding material 100 forms a fillet extending up the exterior of the bump around the entire periphery of the bump. Depending upon the amount of bonding material present at each joint, the wetting properties of the bonding material and the height of bumps 52, the fillet may extend all the way to the outer surface 26 of the dielectric layer 22 or to the outer surface 71 of solder mask layer 70, which effectively forms a part of the outer surface 26 of the dielectric layer. The minimum thickness t of the bonding material layer at the lowermost extremities 74 of the bumps may be quite small or even zero. That is, the convex, dome-shaped bump may touch the contact pad 92 at one or more points. Most preferably, the minimum bonding material layer thickness t is less than 50 microns and preferably less than 25 microns. Thus, the bonding material in the joints can have a thickness comparable to those commonly referred to as a “land grid array.”

As discussed above, the bottom ends of the individual bumps can be displaced slightly upwardly and downwardly, towards and away from the chip independently of one another and can be flattened slightly by applied vertical forces. Thus, the bottom ends 74 of all of the bumps can be brought into engagement with the contact pads 92 by urging the packaged chip towards the circuit panel during bonding, even if the bottom ends of the bumps, the contact pads, or both, are slightly out of plane. Also, the sloping lead-in surfaces on the bumps can help guide the bumps into the apertures 96 in the solder mask layer. A similar action can be provided during engagement with a test fixture having a similar apertured layer.

The solder or other bonding material can be applied to the bumps themselves, or to the contact pads on the circuit panel, using techniques similar to those used in conventional surface-mounting of electronic components. Conventional fluxes may be used. Alternatively, conventional flux-less bonding techniques can be used. When the solder or other bonding material is brought to a liquid state and wets the bumps and contact pads, surface tension of the solder tends to draw each bump towards the center of the associated contact pad.

In the finished assembly, the solder joints provide good resistance to stresses resulting from differential thermal expansion of the components during service and during manufacture. Differences in expansion between chip 46 and circuit panel 90 tend to move contact pads 92 relative to the contacts 64 on the chip. The bottom ends of the bumps can move relative to the chip. Some moveability is imparted by flexure of the bumps themselves. Also, although the present invention is not limited by any theory of operation, it is believed that the bumps can tilt to some degree, as, for example, in the directions indicated by arrow 102 in FIG. 6, as well as bend. Tilting of the bumps may be accompanied by local deformation of dielectric layer 22 and by deformation of the composite supporting layer provided by encapsulant 72 and nubbins 68. Even though there is only a very thin layer of solder present, the bumps provide strain relief action similar to that achieved by conventional solder balls having a height equal to the height of the bumps. Stated another way, the soldered bumps provide strain relief comparable to that of a ball grid array with the small solder volume found in a land grid array. The small solder volume minimizes environmental effects of the solder when the assembly is ultimately disposed of. For example, even where the solder contains a significant proportion of lead, reducing the volume of solder in the assembly reduces lead contamination of the environment. Still further reductions can be achieved by the use of solder with a relatively low proportion of lead.

In a further variant, the solder can be replaced by other bonding materials. For example, conductive polymer compositions such as metal-loaded polymers as, for example, silver-filled epoxies, can be used instead of solders. In a further variant, a layer of an anisotropic bonding material (not shown) may be provided over the contact pads 92 of the circuit panel and the bumps may be engaged with the contact pads, so that there is a thin layer of anisotropic bonding material between at least a part of the bottom end of each bump and the adjacent contact pads. Anisotropic bonding materials conduct in the direction through the layer but do not substantially conduct in the directions along the layer. Typically, such materials include particles of conductive material dispersed in a dielectric material. Additional strain relief can be provided by flexing of leads 36 and deformation of the supporting layer and dielectric layer in areas remote from bumps.

The packaged chip 104 shown in FIG. 8 is similar to the packaged chip discussed above. Packaged chip 104 incorporates a chip carrier having a dielectric layer 122 with traces 138 and downwardly protruding bumps 154 integral with the traces. However, the traces and bumps are disposed on the outer surface 126 of the dielectric layer rather than the inner surface 124. Also, traces 138 are formed integrally with bonding pads 136 facing downwardly or outwardly on the outer surface 126 of the dielectric layer adjacent to a central bond window 128 extending through the dielectric layer. The chip 160 is disposed in a front-face down orientation, with contacts 164 disposed adjacent the center of the chip front surface 162 aligned with the bond window. The chip is secured to the inner surface 124 of the dielectric layer by a thin supporting layer of die attach material such an epoxy 168. The contacts 164 are connected to bond pads 136 by bonding wires 137 applied by a conventional wire bonding process. An encapsulant 172 covers the bond window 128 and bonding wires 137. A solder mask layer 170 covers the traces 138 but terminates short of bonding pads 136. The bumps 154 project downwardly through the solder mask layer. As is apparent from FIG. 8, the downward projection of bumps 154 from the dielectric layer is greater than the projection of the bonding wires 137 and encapsulant 172, so that the bumps can be bonded to pads 192 on a circuit panel 190 and engaged with a test fixture (not shown) without interference by the bonding wires and encapsulant.

Bumps 154 are similar to those discussed above. However, in forming bumps 154, the punch is engaged with the inner surface 124 of the dielectric layer so that the dielectric layer as well as the metallic layer is deformed during the bump formation process, leaving a dielectric liner within each bump. Alternatively, holes can be provided in the dielectric layer above the bump-forming elements of the metallic layer and the punch can be advanced into engagement with the metallic layer through these holes.

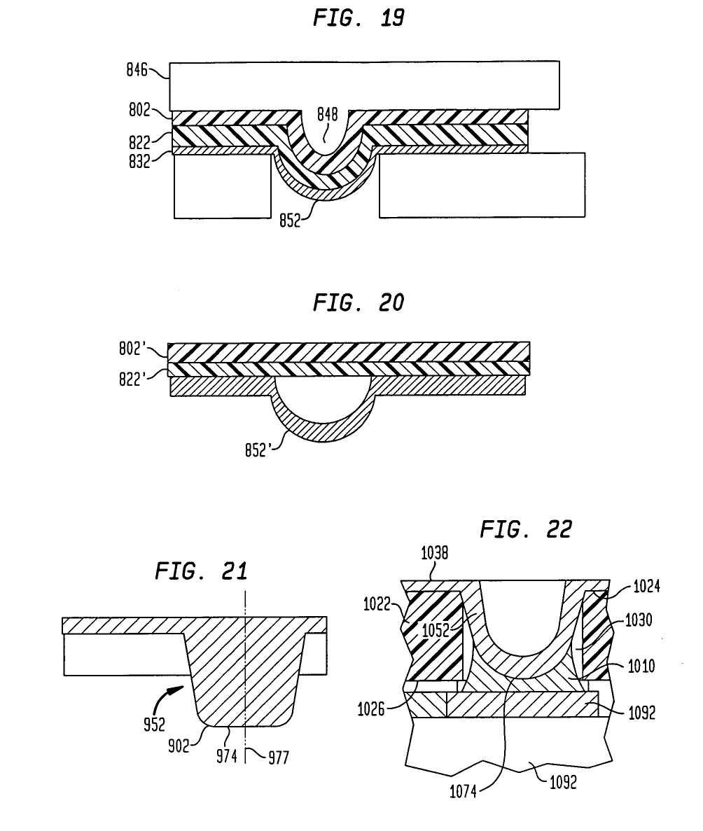

In a further variant (FIG. 19) the metal layer 832, dielectric layer 822 and a layer 802 of a die attach material are provided as a laminate and engaged by a punch 846 so that all of these layers are deformed by the projections 848 on the punch. The deformed portions of the dielectric layer 822 and die attach layer 802 may remain in the positions indicated in FIG. 19, within the interior of the bumps 852. Alternatively, depending upon the resilience of these materials, one or both of the dielectric and die attach layers may spring back partially or completely to the flat condition as shown at 822′ and 802′ in FIG. 20, leaving hollow, unfilled bumps 852′.

The packaged chip depicted in FIG. 9 has traces 238 on the inner or upper surface 224 of the dielectric layer with bumps 254 similar to the bumps discussed above with reference to FIGS. 1-7, projecting through holes in the dielectric layer and formed integrally with the traces 238. Upwardly facing bonding pads 236 are also formed integrally with traces. The traces associated with bond pads 254a and 254b adjacent the center of the package are not illustrated; these traces also extend to bond pads disposed adjacent the edge of the dielectric layer. A composite spacer layer including a solder mask layer 270 and a layer of a die attach 272 separates the bumps and traces from the chip 260. The chip is mounted in face-up orientation overlying the inner surface 224 of the dielectric layer, with the front face 262 and contacts 264 facing upwardly, away from the dielectric layer and with the rear face 266 of the chip facing downwardly toward the dielectric layer. Here again, the contacts 264 on the chip are connected to the bond pads by wire bonds 237. An overmolding 205 such as a relatively rigid epoxy overmolding covers the chip and the upper surface of the supporting layer. Packaged chips of this type can be handled and mounted in the same manner as discussed above.

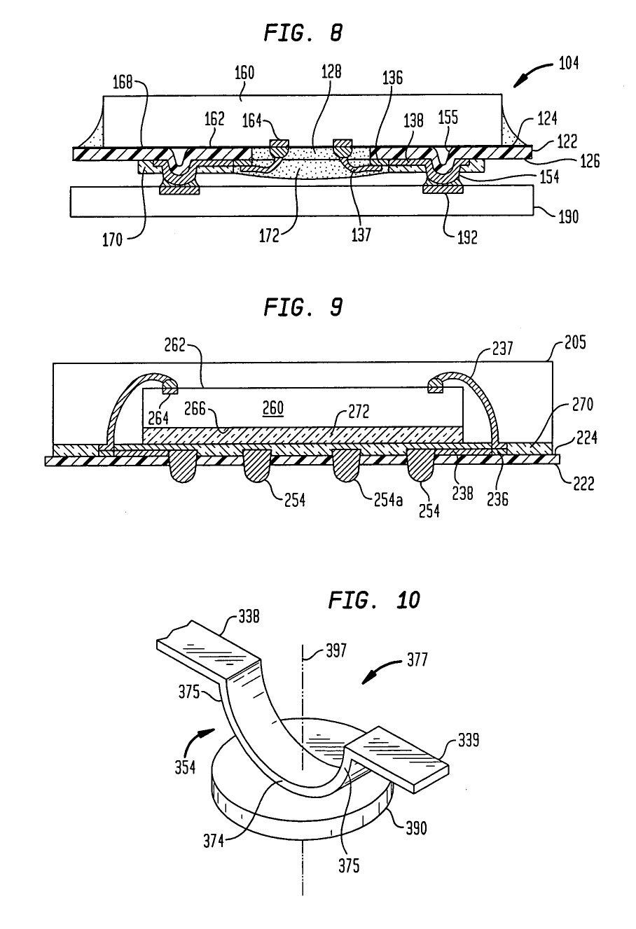

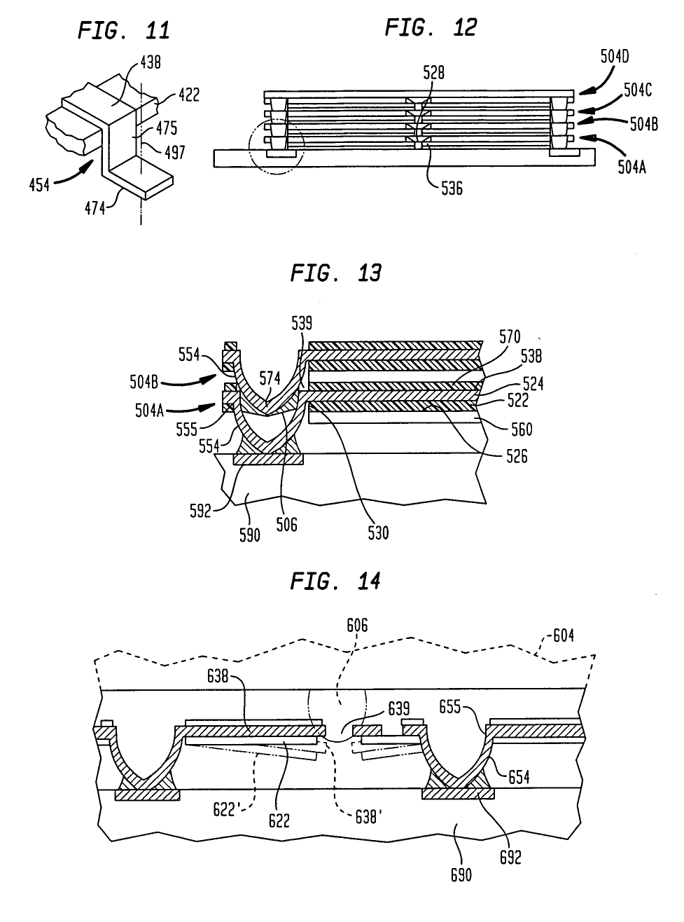

As seen in fragmentary view in FIG. 10, a bump 354 may be formed as a generally U-shaped structure with a closed end defining the base of the U-shape and with a pair of upwardly extending legs 375 defining the open end 377 of the U-shape. One or both of the legs joins with a trace 338 formed integrally with the bump. A leg which does not join a trace may be joined with an anchor 339 which is electrically nonfunctional but which also serves to anchor the bump to the dielectric layer. Bumps of this type can be used in place of the generally cup-shaped bumps discussed above. The bump is mechanically connected to the dielectric layer at trace 338 and at anchor 339, and hence is mechanically connected to the dielectric layer at two or more points on opposite sides of the vertical axis 397 extending through the bottom extremity 374 of the bump. Other bump shapes can be employed, as, for example, a bump having a generally cruciform shape formed by two U-shapes extending in orthogonal planes and crossing one another at the bottom of the bump. Such a bump is mechanically connected to the dielectric layer at four points spaced around the vertical axis through the bottom end of the bump. In a further embodiment (FIG. 11), a bump 454 may be formed as a single projection with a single downwardly extending leg terminating with a bottom part 474 at a level lower than the level of the corresponding trace 438. The bottom part 474 is solder-bonded to a contact pad on the circuit panel in the same manner. Such a bump is connected to the dielectric layer 422 on only one side of the vertical axis 497 through the bottom extremity 474 of the bump as, for example, at trace 438. For a given bump height and metal thickness, a bump connected in this manner typically will be more flexible than a closed bump such as that discussed above with reference to FIGS. 1-7 or a bump connected at multiple points such as the U-shaped bump of FIG. 10.

An assembly shown in FIGS. 12 and 13 includes a plurality of units 504 in a stacked arrangement. Each unit 504 includes a chip carrier having a dielectric layer 522 and bumps 554 formed integrally with the traces projecting downwardly from the traces and downwardly from the dielectric layer, the bumps extending through bump openings 530 in the dielectric layer. In this arrangement, however, chip 560 is mounted on the outer side 526 of the dielectric layer and connected by leads 526 interior with the traces (FIG. 12) extending through a bond window 528 in the dielectric layer to the contacts on the chip or by wire bonds (not shown). Bumps 554 are generally cup-shaped and similar to the bumps discussed above with reference to FIGS. 1-7. However, the bumps 554 of each unit project downwardly beyond the dielectric layer 522 and downwardly beyond the chip 560 so that the lowermost unit (the unit at the bottom in FIGS. 12 and 13) can be mounted on a circuit panel 590 and the bumps can be bonded to contact pads 592 in the same manner as discussed above with reference to FIGS. 1-7. Each unit 504 has a solder mask layer 570 overlying the traces 538 of the unit.

The solder mask layer has openings 539 aligned with the bumps, leaving the open top ends 555 of the bumps exposed at the top surface of the unit. The units desirably are substantially identical to one another, with their bumps disposed in the same manner and locations. Thus, the units can be stacked on one another as illustrated in FIGS. 12 and 13. The bottom ends 574 of bumps 554 on the second unit 504b are received in the open top ends 555 of the bumps 554 in the first or lowermost unit 504a. Similarly, the bumps of unit 504c are received in the open top ends of the bumps in unit 504b and the bumps in the top unit 504d are received in the open top ends of the bumps in unit 504c. Any number of units can be stacked in this manner. The stacked units can be solder bonded as by solder 506. Also, each unit can serve as a test socket for the next higher unit. For example, the assembly of circuit panel 590 and bottom unit 504a can be used as a test socket for unit 504b or for another device having a similar bump layout. The closed bottom ends of the bumps in the unit under test make good contact with the interiors of the open top ends 555 of the bumps on the test socket. If the test is successful, the units can be separated from one another and solder can be introduced to bond the units to one another. Alternatively, an assembly of a circuit panel and a chip carrier, such as the chip carrier of unit 504a, can be used as a permanent test socket for testing other devices. The overall layout of the stacked assembly can be generally as described in co-pending, commonly assigned PCT International Application No. PCT/US02/32251, the disclosure of which is also incorporated by reference herein. As discussed therein, the conductive elements of stacked units form vertical busses. In assemblies as shown in FIGS. 12 and 13, the vertical busses are formed by stacked, interconnected bumps 554. As further discussed in the '351 international application, all of the units can be substantially identical to one another except that selective interconnection is provided between the vertical busses and chip select contacts on the chip within each unit. Typically, different units have chip select contact connected to different busses.

In a variant of the unit construction shown in FIG. 12, the chip can be disposed beneath the dielectric layer with the rear surface of the chip facing upwardly toward the outer surface of the dielectric layer. In yet another variant, a stacked structure can be made with individual units each having a chip overlying the inner or upwardly-facing surface of the dielectric layer. In such a structure, the bumps on each unit extend downwardly past the chip on the next lower unit. The structure of each unit may be similar to the packaged chips shown in FIGS. 1-9, except that some or all of the bumps are disposed outside the periphery of the chip so that the bumps on the stacked units can be engaged with one another.

A test socket according to yet another embodiment of the invention includes a substrate 690 such as a circuit panel and a flexible dielectric element 622 having bumps 654 projecting downwardly therefrom, the bumps being formed integrally with traces 638 on the dielectric element. The traces terminate in socket openings 639. The bumps 654 support the dielectric element 622 above the substrate 690 and electrically interconnect the test sockets 639 with the contact pads 692 of the substrate and with leads (not shown) in the substrate. Desirably, the bumps 654 are provided in a grid pattern as are the socket openings 639. The grid of socket openings 639 is interspersed with the grid of bumps 654 so that each socket opening 639 is surrounded by a plurality of bumps 654. The bumps 654 serve as supporting posts and perform the functions of the supporting posts as described in U.S. Pat. No. 6,086,386, the disclosure of which is hereby incorporated by reference herein. The test socket can be used to test a microelectronic unit 604 having projecting elements 606 which may be bumps, solder balls or other projecting elements. In the manner described in the '386 patent, when a unit 604 being tested is pressed downwardly into engagement with the test socket, the projections 606 on the unit engage the socket opening 639 and thence are electrically connected to traces 638 and bumps 654 and thence connected to the substrate. The dielectric element 622 and traces 638 can deform as indicated in broken line 622′ and 638′. This action is similar to the action of the flexible socket discussed in the '386 patent. However, the use of bumps formed integrally with traces 638 greatly simplifies construction of the socket. Alternatively, the open ends 655 of the bumps can be employed as openings for receiving the projections of the unit under test as discussed above with reference to FIGS. 12 and 13.

Numerous variations and combinations of the features discussed above can be utilized without departing from the present invention. For example, more than one chip can be mounted on a chip carrier. Multiple chips can be mounted on opposite sides of the chip carrier, stacked on one side of the chip carrier or arrayed on one or both sides so that chips are disposed side by side. In a further arrangement, bumps may be used in place of terminal pads and solder balls in a folded chip carrier or assembly as discussed in U.S. Pat. No. 6,121,676 and in commonly assigned, co-pending U.S. Provisional Application Ser. Nos. 60/401,391 and 60/403,939, the disclosures of which are also incorporated by reference herein.

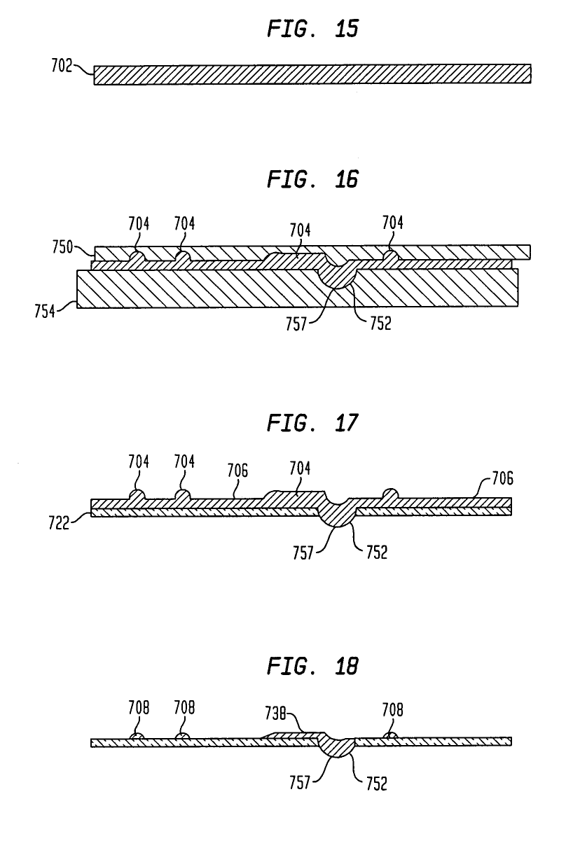

In yet another arrangement, a metal layer such as a continuous sheet of metal can be deformed to form the bumps before the metal layer is united with the dielectric layer as, for example, engaging the metal layer between a punch and die as discussed above. The metal layer can then be etched using a conventional photoresist as an etch mask to form traces and other features such as bonding pads and leads. In a further variant, the process of forming the bumps may be integrated with a process of forming the traces and other features of the type shown in U.S. Pat. No. 6,083,837, the disclosure of which is hereby incorporated by reference herein. A layer of metal 702 having substantially uniform thickness (FIG. 15) is engaged between tools such as 750 and 754 (FIG. 16) to form bumps 752 and also to form relatively thick regions 704 in areas where traces, leads and other features are to be formed and relatively thin regions 706 in other parts of the sheet. Following this deformation or “coining” process, the metal layer is united with a dielectric layer 722 (FIG. 17) and then etched for a time sufficient to completely remove the metal in thin regions 706 but insufficient to completely remove the metal in the thick regions 704 and bumps 752. This leaves the bumps 752, traces 738 and other metallic features 708. The dielectric layer may overlie either side of the metal layer, and may be applied either as a pre-formed dielectric layer or as a coating on the metal layer which is cured to form a coherent dielectric layer prior to etching the metal. In a further variant, coining step used to form the thin and thick regions of the metal layer may be performed in a separate operation from the deforming step used to make the bumps. In the embodiment of FIGS. 15-17, the die 754 (FIG. 16) has cavities which are in the form of the desired bump shape, so that at least the bottom end of the bump is formed by contact with the die. Such a die can be used in the other embodiments discussed herein. Also, the die can be provided with one or more small indentations or grooves to form raised features such as a microscopic projection 757 on the bottom end of the bump or raised ridges (not shown) extending along the bottom or side walls of the bump. Such raised features may have sharp corners or edges, and facilitate good contact with test fixtures and/or contact pads.

In a further variant, processes such as electroplating can be employed to form the bumps. For example, the metallic layer can be formed with bumps by electroplating it on a male mandrel having projections corresponding to the bumps to be formed or on a female mold having recesses corresponding to the bumps to be formed. Where the bumps are formed by mechanical deformation, a punch with projections as discussed with reference to FIG. 3 can be used with a cushion of a relatively hard, resilient material in place of the die. Also, regardless of the method used to form the bumps, the bumps may be solid, metal-filled structures such as the bump 952 depicted in FIG. 21. Bumps of this type can be formed without indenting the top of the metallic layer, and accordingly can be formed by a die having cavities in the desired bump shape opposed by a flat tool. Bump 952 has a bottom extremity 974 which is flat and horizontal in the immediate vicinity of the central vertical axis 977, but which also has a sloping or curved edge surface 902 defining the margins of the bottom extremity, remote from the axis. This sloping or curved edge surface 902 provides a lead-in similar to the lead-in provided by the curved bottom surface 74 of the bump discussed above with reference to FIGS. 1-7. In a further variant, the flat bottom extremity may extend all the way to the edges of the bump, where it joins with the vertically-extensive wall of the bump. Flat bottom extremities can be provided on hollow bumps as well as on solid bumps. The flat bottom extremity of the bump further minimizes the amount of solder or other bonding material needed to join the bottom extremity to a contact pad of a circuit panel.

In a further variant (FIG. 22), the bump 1052 projects downwardly from a trace 1038, but does not project beyond the bottom surface 1026 of dielectric layer 1022. Although the bumps are recessed from bottom surface 1026 within openings 1030, they are nonetheless exposed at the bottom surface and hence accessible for connection from the bottom surface. As used in this disclosure, a metallic feature can be considered “exposed at” a surface of a dielectric layer if the metallic feature is accessible to a contact or bonding material applied to such surface. Thus, a metallic feature which projects from the surface of the dielectric (such as the bumps 52 of FIGS. 1-7) or which is flush with the surface of the dielectric is also “exposed at” such surface.

When the packaged chip of FIG. 22 is attached to a circuit panel, solder or other bonding material 1010 extends upwardly from pad 1092 to the bottom end 1074 of the bump, and bonds to the bump within the bump opening 1030 of the dielectric layer. Here again, the quantity of bonding material required to form the joint is substantially less than that which would be required with flat pads at the top surface 1024. The dielectric layer may constrain the bonding material during bonding and thus further limit the volume of bonding material required. Also, the downwardly-projecting bumps in this embodiment as well tend to minimize stress on the bonding material.

As these and other variations and combinations of the features discussed above can be utilized without departing from the present invention as defined by the claims, the foregoing description of the preferred embodiment should be taken by way of illustration rather than by way of limitation of the invention.

1. A packaged chip comprising:
(a) a chip having front and rear surfaces and contacts on said front surface;
(b) a chip carrier attached to said chip, said chip carrier including a dielectric layer extending across one surface of said chip and having an inner surface facing upwardly and an outer surface facing downwardly, said chip carrier having conductive traces thereon electrically connected to said contacts and conductive bumps formed integrally with said traces, said conductive bumps projecting downwardly from said traces, said bumps having bottom ends exposed at the outer surface of said dielectric layer for bonding to contact pads on a circuit panel.

2. A packaged chip as claimed in claim 1 wherein at least one of said bumps has a first wall portion extending downwardly from one of said traces, a bottom wall portion joining said first wall portion adjacent the bottom end of the bump, and a second wall portion extending upwardly from said bottom wall portion to said dielectric layer.

3. A packaged chip as claimed in claim 1 wherein at least one of said bumps is generally U-shaped, with a closed end of the U-shape defining the bottom end of the bump and an open end of the U-shape facing upwardly.

4. A packaged chip as claimed in claim 1 wherein at least one of said bumps is generally cup-shaped, with a closed end of the cup shape defining the bottom end of the bump and an open end of the cup shape facing upwardly.

5. A packaged chip as claimed in claim 1 wherein at least one said generally cup-shaped bump has an imperforate side wall extending upwardly from the bottom end of the bump to said dielectric layer.

6. A packaged chip as claimed in claim 1 wherein at least one of said bumps is substantially solid.

7. A packaged chip as claimed in claim 1 wherein at least one of said bumps has an exterior surface in the form of a surface of revolution about a vertical axis.

8. A packaged chip as claimed in claim 1 wherein at least one of said bumps has a lead-in surface sloping upwardly and outwardly around the entire periphery of the bump adjacent the bottom end of the bump.

9. A packaged chip as claimed in claim 1 wherein at least some of said bumps are disposed in one or more rows at a pitch of 1 mm or less.

10. A packaged chip as claimed in claim 1 wherein said dielectric layer extends beneath said chip, and said inner surface of said dielectric layer faces upwardly toward said chip.

11. A packaged chip as claimed in claim 10 wherein at least some of said bumps are disposed beneath said chip.

12. A packaged chip as claimed in claim 11 wherein all of said bumps are disposed beneath said chip.

13. A packaged chip as claimed in claim 1 wherein said traces are disposed above the outer side of said dielectric layer and said bumps extend at least partially through said dielectric layer.

14. A packaged chip as claimed in claim 13 wherein said traces are disposed on the inner side of said dielectric layer and said bumps extend at least partially through said dielectric layer.

15. A packaged chip as claimed in claim 1 wherein said traces are disposed on the outer side of said dielectric layer.

16. A packaged chip as claimed in claim 10 wherein said front surface of said chip faces downwardly towards said chip carrier.

17. A packaged chip as claimed in claim 16 wherein said chip carrier has leads formed integrally with said traces, said leads being bonded to said contacts of said chip.

18. A packaged chip as claimed in claim 16 further comprising downwardly-facing bonding pads on said chip carrier electrically connected to said traces and bond wires connecting said bonding pads to said contacts.

19. A packaged chip as claimed in claim 18 wherein said bond wires do not extend below the bottom ends of said bumps.

20. A packaged chip as claimed in claim 10 wherein said rear surface of said chip faces downwardly towards said chip carrier.

21. A packaged chip as claimed in claim 20 further comprising upwardly-facing bonding pads on said chip carrier electrically connected to said traces and bond wires connecting said bonding pads to said contacts.

22. A packaged chip as claimed in claim 1 wherein the bottom ends of said conductive bumps are movable with respect to said chip.

23. A packaged chip as claimed in claim 22 wherein the bottom ends of said conductive bumps are movable in a vertical direction towards or away from said chip.

24. A packaged chip as claimed in claim 23 wherein the bottom ends of said conductive bumps are movable in horizontal directions parallel to said surfaces of said chip.

25. A packaged chip as claimed in claim 1 further comprising a spacer layer disposed between said chip and said dielectric layer.

26. A packaged chip as claimed in claim 23 wherein said spacer layer is compliant.

27. A packaged chip as claimed in claim 1 wherein said chip is disposed beneath said dielectric layer and said bumps project downwardly from said dielectric layer beyond said chip.

28. A packaged chip as claimed in claim 25 wherein said front surface of said chip faces toward said outer surface of said dielectric layer.

29. A packaged chip as claimed in claim 1 wherein said bottom ends of said bumps are disposed below said outer surface of said chip carrier.

30. A packaged chip as claimed in claim as claimed in claim 1 wherein said dielectric layer has bump openings therein and said bumps project downwardly from said traces within said bump openings, said bottom ends of said bumps being disposed within said bump openings above said outer surface of said dielectric layer.

31. A coherent, self-supporting chip carrier comprising:
(a) a dielectric layer having an inner surface facing upwardly and an outer surface facing downwardly,
(b) conductive traces on said dielectric layer; and
(c) conductive bumps formed integrally with said traces, said conductive bumps projecting downwardly from said traces, said bumps having bottom ends adapted for bonding to contact pads on a circuit panel.

32. A chip carrier as claimed in claim 31 wherein at least one of said bumps has a first wall portion extending downwardly from one of said traces, a bottom wall portion joining said first wall portion adjacent the bottom end of the bump, and a second wall portion extending upwardly from said bottom wall portion to said dielectric layer.

33. A chip carrier as claimed in claim 31 wherein at least one of said bumps is generally U-shaped, with a closed end of the U-shape defining the bottom end of the bump and an open end of the U-shape facing upwardly.

34. A chip carrier as claimed in claim 31 wherein at least one of said bumps is generally cup-shaped, with a closed end of the cup shape defining the bottom end of the bump and an open end of the cup shape facing upwardly.

35. A chip carrier as claimed in claim 34 wherein at least one said generally cup-shaped bump has an imperforate side wall extending upwardly from the bottom end of the bump to said dielectric layer.

36. A chip carrier as claimed in claim 34 wherein at the open top end of least one said cup-shaped bump is exposed at the inner surface of said dielectric layer.

37. A chip carrier as claimed in claim 31 wherein at least one of said bumps is substantially solid.

38. A chip carrier as claimed in claim 31 wherein at least one of said bumps has an exterior surface in the form of a surface of revolution about a vertical axis.

39. A chip carrier as claimed in claim 31 wherein at least one of said bumps has a lead-in surface sloping upwardly and outwardly around the entire periphery of the bump adjacent the bottom end of the bump.

40. A chip carrier as claimed in claim 31 wherein at least some of said bumps are disposed in one or more rows at a pitch of 1 mm or less.

41. A chip carrier as claimed in claim 31 wherein said traces are disposed above the outer side of said dielectric layer and said bumps extend at least partially through said dielectric layer.

42. A chip carrier as claimed in claim 41 wherein said traces are disposed on the inner side of said dielectric layer and said bumps extend at least partially through said dielectric layer.

43. A chip carrier as claimed in claim 42 wherein said bumps extend entirely through said dielectric layer and the bottom ends of the bumps are disposed below the outer surface of the dielectric layer.

44. A chip carrier as claimed in claim 31 wherein said traces are disposed on the outer side of said dielectric layer.

45. A chip carrier as claimed in claim 44 wherein said bumps include hollow cup-shaped bumps having open top ends and said dielectric layer extends across the open top ends of at least some of said bumps.

46. A chip carrier as claimed in claim 45 wherein hollow bumps define interior spaces and said dielectric layer extends into the interior spaces of at least some of said bumps.

47. A microelectronic assembly comprising:
(a) a packaged semiconductor chip including:
(i) a chip having front and rear surfaces and contacts on said front surface;
(ii) a chip carrier including a dielectric layer having traces thereon electrically connected to said contacts and bumps integral with said traces, said dielectric layer having an inner surface facing upwardly toward said chip and an outer surface facing downwardly away from said chip, said bumps projecting downwardly from said traces and having bottom ends;
(b) a circuit panel having a top surface and contact pads exposed at said top surface, said bottom ends of said bumps on said chip carrier being bonded to said contact pads on said circuit panel.

48. An assembly as claimed in claim 47 wherein the bottom surface of said chip carrier is spaced vertically from said contact pads by said bumps.

49. An assembly as claimed in claim 47 further comprising an electrically conductive bonding material securing said bumps to said contact pads.

50. An assembly as claimed in claim 49 wherein said conductive bonding material has a minimum thickness less than 50 μm.

51. An assembly as claimed in claim 50 wherein at least some of said bumps define vertically-extensive wall surfaces extending upwardly from the bottom ends of the bumps and said bonding material forms fillets extending from said contact pads to locations on said wall surfaces above the bottom ends of the bumps defining said wall surfaces.

52. An assembly as claimed in claim 51 wherein said wall surfaces and said fillets extend entirely around at least some of said bumps.

53. An assembly as claimed in claim 52 wherein the bottom ends of said bumps are convex and define a bottom extremity surface merging smoothly with said wall surfaces, and wherein said contact pads are substantially flat.

54. A method of making a microelectronic assembly comprising the steps of:
(a) temporarily engaging a chip assembly including a chip, a chip carrier including a dielectric layer having traces thereon electrically connected to contacts on the chip and bumps integral with the traces with a test fixture so that bottom ends of the bumps projecting downwardly from the traces and projecting downwardly beyond the dielectric layer engage test contacts on the fixture;
(b) testing the chip assembly by transmitting signals between at least some of the engaged bumps and test contacts;
(c) disengaging the chip assembly from the test fixture; and
(d) mounting the tested chip assembly on a circuit panel by bonding the bottom ends of the bumps to contact pads on the circuit panel.

55. A method as claimed in claim 54 wherein, during said step of temporarily engaging, the bottom ends of at least some of said bumps are displaced vertically relative to the bottom ends of others of said bumps.

56. A method as claimed in claim 55 wherein, during said step of temporarily engaging, at least some of said bumps are deformed.

57. A method of making a chip carrier comprising the steps of:
(a) uniting a metal with a dielectric layer having inner and outer surfaces;
(b) forming traces on said dielectric layer from said metal; and
(c) forming metallic bumps by deforming said metal; said uniting, bump-forming and trace-forming steps being performed so that said bumps are integral with said traces and project downwardly from said traces.

58. A method as claimed in claim 57 wherein said bump-forming step is performed after said uniting step.

59. A method as claimed in claim 58 wherein said dielectric layer has openings therein and said bump-forming step is performed so as to deform the metal through at least some of said openings.

60. A method as claimed in claim 59 wherein said deforming step is performed after said trace-forming step.

61. A method as claimed in claim 58 wherein said bump-forming step includes engaging the metal with a tool having projections and moving the tool downwardly relative to the metal so as to form the metal around said projections.

62. A method as claimed in claim 58 wherein said bump-forming step includes engaging said dielectric layer and said metal with a tool and moving said tool so as to deform both said dielectric layer and said metal.

63. A method as claimed in claim 62 wherein said dielectric layer has inner and outer surfaces and said uniting step is performed so as to provide said metal remote from said inner surface of said dielectric layer, the method further comprising providing a spacer layer on said inner surface of said dielectric layer prior to said bump-forming step, said spacer layer being deformed during said bump-forming step.

64. A method as claimed in claim 63 wherein said spacer layer includes an adhesive.

65. A method as claimed in claim 58 wherein said metal is initially in the form of a layer of metal of substantially uniform thickness and wherein said trace-forming step includes deforming the metal to form relatively thick regions and relatively thin regions during the step of deforming the metal to form said bumps, and subsequently removing said relatively thin regions to leave metal in said relatively thick regions as said traces.

66. A socket comprising:
(a) a dielectric layer;
(b) a plurality of unitary, hollow metallic bumps having at least partially closed bottom ends and open top ends mounted on said dielectric layer; and
(c) a substrate having a top surface and contact pads exposed at said top surface, the bottom ends of said bumps being bonded to said contact pads so that said bumps support said dielectric layer above said substrate, the top ends of said bumps being adapted to receive terminals of a microelectronic element to be tested.

67. A socket as claimed in claim 66 wherein said hollow bumps are generally cup-shaped.

68. A socket comprising:
(a) a substrate;
(b) a dielectric layer having thereon test contacts, traces and bumps formed integrally with said traces, said bumps projecting downwardly from said traces and said dielectric layer, said bumps having bottom ends disposed below said dielectric layer, said bumps being interspersed with said test contacts so that said test contacts are offset in horizontal directions from said bumps; and
(c) a substrate having contact pads thereon, said bumps being bonded to said contact pads and supporting said dielectric layer above said substrate, whereby when terminals of a device to be tested are engaged with said test contacts, said test contacts can be displaced downwardly by flexure of said dielectric layer.
